(19) United States
(12) Patent Application Publication
(10) Pub. No.: US 2012/0148186 A1
(43) Pub. Date: Jun. 14, 2012

(54) PROCESS FOR FABRICATING SEMICONDUCTOR DEVICES AND SEMICONDUCTOR DEVICES

(75) Inventor: Emmanuelle Vigier-Blanc, Le Sappey Chartreuse (FR)

(73) Assignee: STMICROELECTRONICS (GRENOBLE 2) SAS, Grenoble (FR)

(21) Appl. No.: 13/304,777

(22) Filed: Nov. 28, 2011

(30) Foreign Application Priority Data
Dec. 8, 2010 (FR) 1060248

(51) Int. Cl. G02B 6/12; H01L 21/50

(52) U.S. Cl. 385/14; 438/113; 257/E21.499

(57) ABSTRACT

A process for fabricating semiconductor devices provides a wafer of integrated circuits, permanently attaches an optical wafer to the wafer of integrated circuits, and temporarily attached a supporting wafer to the optical wafer. The supporting wafer provides structural support during further fabrication processes where a back side of the wafer of integrated circuits is thinned and through silicon vias are formed. The supporting wafer is then removed and the wafer of integrated circuits with the optical wafer is singulated into individual integrated-circuit chips.

### PRIORITY CLAIM

This application claims priority from French Application for Patent No. 1060248 filed Dec. 8, 2010, the disclosure of which is hereby incorporated by reference.

### TECHNICAL FIELD

The present invention relates to the field of semiconductor devices, and more particularly to optical semiconductor devices.

### BACKGROUND

Fabrication of integrated-circuit chips comprising electrical connection vias passing through the substrate (often called through silicon vias or TSVs) and back-side external electrical connection means require wafers for wafer-scale chip fabrication to be mounted on thick wafers, these wafers being on the integrated-circuit side.

In the particular case where the chips comprise optical elements such as elements that collect or emit light rays, the wafers, which are chosen because the light rays can pass through them, remain fixed to the wafers/substrates for wafer-scale chip fabrication, so that the optical semiconductor devices obtained after singulation comprise thick optical plates in front of their optical elements, tending thereby to interfere with the path of the light rays that pass through them.

Such optical semiconductor devices are used in imaging apparatus, especially in medical imaging apparatus, and in geophysics and astrophysics.

### SUMMARY

A process for fabricating semiconductor devices is provided.

This process may comprise: producing a wafer of integrated circuits comprising a substrate wafer and, on a front side of the latter and in various locations, a plurality of integrated circuits, this wafer of integrated circuits having a front side on the side facing these integrated circuits; producing a stack comprising a first wafer above the front side of the wafer and a second wafer above the first wafer; producing, in the various locations, holes through the substrate wafer by way of the back side of the latter and filling these holes with a conductive material so as to obtain electrical connection vias selectively connected to the integrated circuits; producing, in the various locations, back-side external electrical connection means on the back side of the substrate wafer, these back-side electrical connection means being selectively connected to the electrical connection vias; removing or demounting the second wafer; and singulating the semiconductor devices obtained in the locations, each semiconductor device obtained comprising an integrated-circuit chip that includes a portion of the wafer of integrated circuits and a plate that includes a portion of the first wafer.

This process may comprise: producing a thick wafer of integrated circuits, comprising a thick substrate wafer; producing said stack; thinning, by way of its back side, the thick substrate wafer so as to obtain a thinned wafer of integrated circuits; and producing said holes in the thinned substrate wafer.

The first wafer may be fixed to the front side of the wafer of integrated circuits so as to be irremovable by way of a permanent adhesive layer, each semiconductor device obtained possibly including a portion of this adhesive layer.

The second wafer may be removably fixed to the first wafer by way of a temporary or non-permanent adhesive layer.

The first and second wafers may be made of the same material.

The second wafer may be thicker than the first wafer.

The integrated circuits may comprise optical elements for collecting or emitting light rays, at least the first wafer being an optical wafer that the light rays can pass through.

A semiconductor device is also provided, which device comprises a wafer of integrated circuits comprising integrated circuits including optical elements and provided, in front of these optical elements, with a stack of at least two wafers, one wafer of which is an optical wafer located on the side of the optical elements.

The optical wafer may be thinner than the other wafer.

The optical wafer may be fixed to the wafer of integrated circuits by way of a permanent adhesive layer and the other wafer may be joined to the optical wafer by way of a temporary or non-permanent adhesive layer.

A semiconductor device is also provided, comprising a chip of integrated circuits, of reduced thickness, comprising integrated circuits including an optical element and provided with an optical plate, of reduced thickness, the plate being placed on the chip of integrated circuits, in front of the optical element. Such a device may be used in an imaging apparatus.

### BRIEF DESCRIPTION OF THE DRAWINGS

A semiconductor device and a process for its fabrication will now be described by way of non-limiting examples, illustrated by the drawings in which:

FIG. 1 shows a cross section of an optical semiconductor device; and

FIGS. 2 to 7 show in cross section the optical semiconductor device of FIG. 1 at different stages in its fabrication.

### DETAILED DESCRIPTION OF THE DRAWINGS

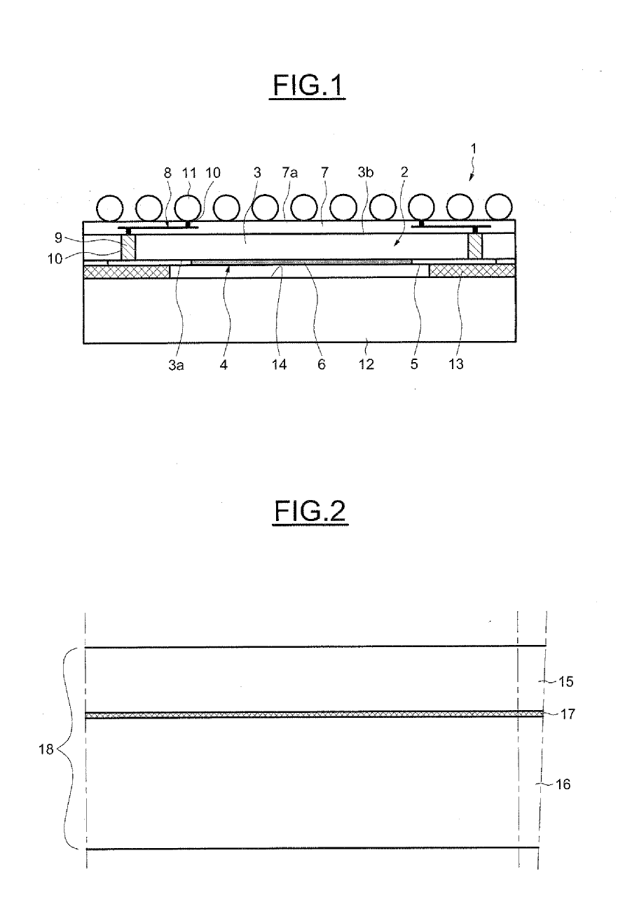

An optical semiconductor device 1, illustrated in FIG. 1, comprises an integrated-circuit chip 2 that comprises integrated circuits 4 on a front side 3a of a reduced-thickness substrate 3. These integrated circuits define a central region of the front side 5 of the chip 2, an integrated optical element 6, for example a CMOS optical sensor provided with microlenses and able to collect light rays. In a variant embodiment, this integrated optical element 5 could be adapted to emit light rays.

In a back-side layer 7, formed on the back side 3b of the substrate 3 and having an outer back side 7a, the chip 2 comprises a back-side external electrical connection network 8 that is selectively connected to the integrated circuits 4 by way of a plurality of electrical connection through silicon vias 9 contained in holes 10 passing through the substrate 3. The back-side external electrical connection network 8 is provided with external electrical connection elements 11 such as metal bumps.

For example, the chip 2 may have, between its front side 5 and its back side 7a, a thickness lying between 50 and 100 microns.

The optical semiconductor device 1 furthermore comprises a thin or reduced-thickness front optical plate 12 that is placed on the chip 2, and which is fixed to the front side 5 of the latter by way of a permanent adhesive layer 13. This adhesive layer 13 extends over a peripheral region of the front side 5 of the chip 2 and over a peripheral region of the back side 14 of the front plate 12, the inside edge of the adhesive layer 13 being a distance from the peripheral edge of the optical sensor 6, so as not to cover the latter.

For example, the front optical plate 12 may have a thickness lying between 50 and 300 microns and the adhesive layer 13 may have a thickness lying between a few microns and a few tens of microns.

The adhesive layer 13 may be a photoresist, for example of the benzocyclobutene or siloxane type.

In a variant embodiment, the front plate 12 may be made of transparent glass and could be treated or covered with a suitable layer, for example so as to form an optical filter.

In a variant embodiment, if the adhesive is transparent, the adhesive layer 14 could fill all the space between the chip 2 and the front plate 12 and cover the optical sensor 5.

A possible way of fabricating optical semiconductor devices 1, for example by wafer-scale processing, will now be described with reference to FIGS. 2 to 6.

As illustrated in FIG. 2, a first wafer 15 is joined to a second wafer 16, by way of a non-permanent or temporary but sufficiently resistant adhesive layer 17, so as to obtain a stack 18. The first wafer 15 corresponds, in terms of both thickness and material, to the plate 12 of the optical semiconductor devices 1 to be obtained.

The second wafer 16 may be thicker than the first wafer 15. For example, the second wafer 16 may have a thickness lying between 400 and 1000 microns.

The second wafer 16 may be made of the same base material as or of similar materials to the first wafer 15, so that they have equal or very similar expansion coefficients.

In a variant embodiment, it could be possible to assemble two thick plates 15 and 16 and then to thin the plate 15 so as to obtain the thickness desired for the latter.

The non-permanent or temporary adhesive layer 17 may be made of epoxide and acrylate and have a thickness lying between a few microns and a few tens of microns.

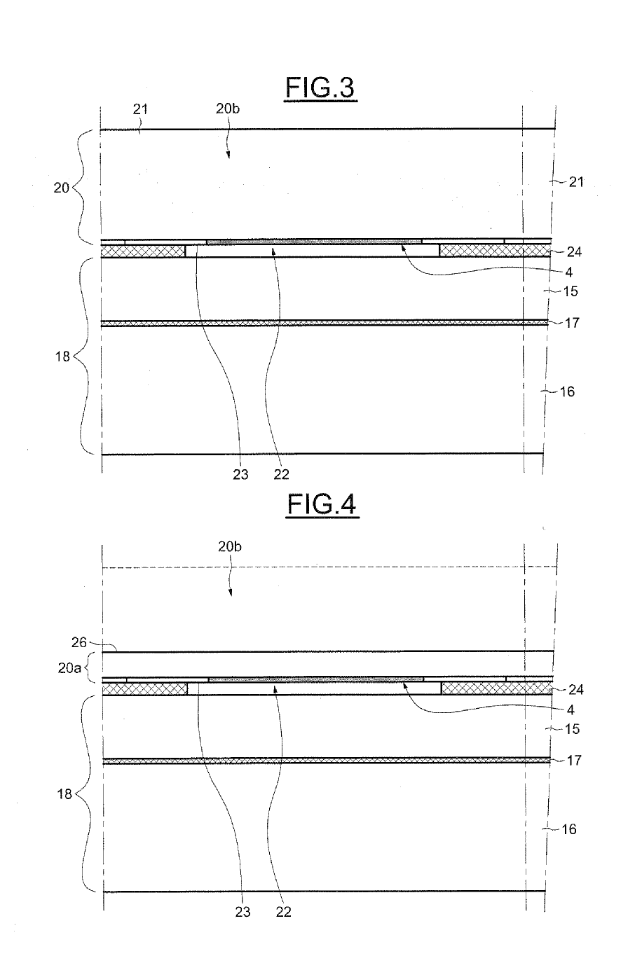

As illustrated in FIG. 3, it is possible to have prefabricated a thick wafer 20 of integrated circuits, which comprises a thick substrate wafer 21 on a front side of which is formed, in locations 22, a plurality of integrated circuits 2 above which the thick prefabricated wafer of integrated circuits 20 has a front side 23.

The stack 18 is then mounted on the thick wafer 20 of integrated circuits. To do this the back side 24 of the first wafer 16, opposite the second wafer 17, is bonded to the front side 23 of the prefabricated thick wafer 20 of integrated circuits by way of a permanent adhesive layer 24 that corresponds, in each location 22, to the adhesive layer 13 of the optical semiconductor devices 1 to be obtained. The adhesive layer 24 may be a photoresist, for example of the benzocyclobutene or siloxane type.

According to a variant embodiment, it would be possible to first fix the first wafer 15 to the front side 23 of the thick prefabricated wafer 20 of integrated circuits, by way of the permanent adhesive layer 24, and then assemble the second wafer 16 on the wafer 15 by way of the non-permanent or temporary adhesive layer 17. The stack 18 could be obtained in the same way on the front side 23 of the thick prefabricated wafer 20.

Next, as illustrated in FIG. 4, the substrate wafer 21 is thinned by removing its back-side part so as to obtain a reduced-thickness substrate wafer 25 the thickness of which corresponds to the thickness of the substrate 3 of the optical semiconductor devices 1 to be obtained. This operation may be carried out using a chemical-mechanical or mechanical process, for example polishing. A thinned wafer 20a of integrated circuits is then obtained.

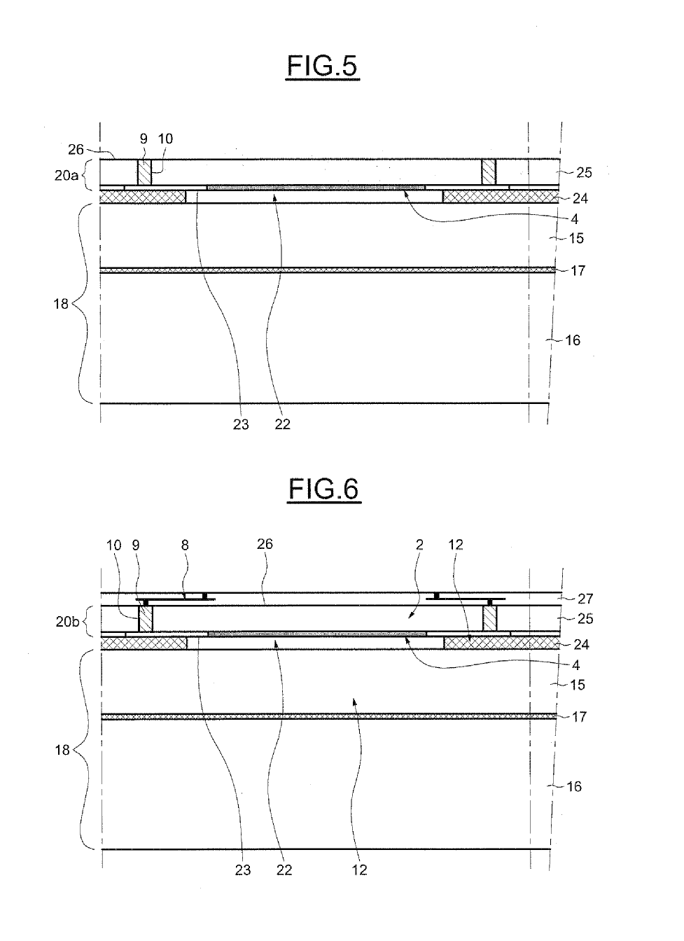

Next, as illustrated in FIG. 5, in each location 22, by way of the back side 26 of the reduced-thickness substrate wafer 25, holes 10 are produced in this substrate wafer 25 and these holes 10 are filled so as to form the through silicon vias 9 of the optical semiconductor devices 1 to be obtained.

Next, as illustrated in FIG. 6, on the back side 26 of the reduced-thickness substrate wafer 25, a layer 27 is produced that, in each location 22, corresponds to the layer 6 and integrates a back-side electrical connection network 8. A complete wafer 20b of integrated circuits is then obtained.

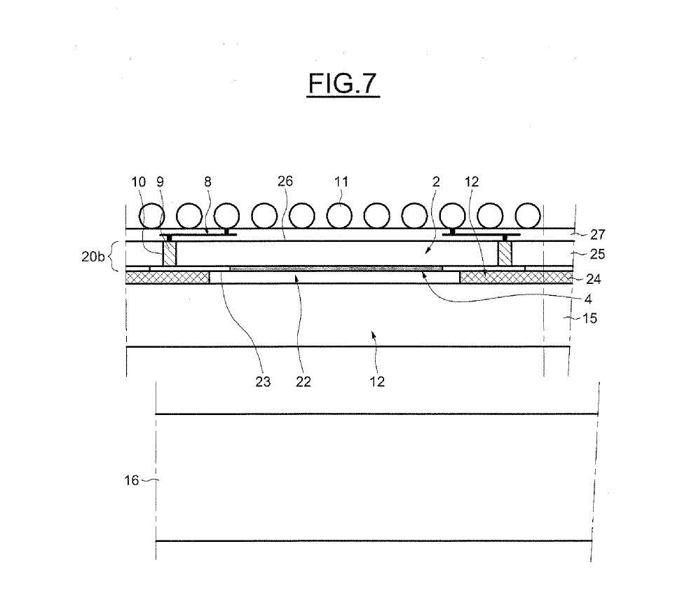

After which, as illustrated in FIG. 7, the second wafer 16 is removed or demounted by destroying the temporary or non-permanent adhesive layer 17, for example by applying a high temperature, about 175° C., and by sliding the wafer 16 relative to the wafer 15.

Next, it is possible to clean the exposed side of the first wafer 15 so as to remove any residue of the adhesive layer 17.

Next, each location 22 is provided with back-side external electrical connection elements 11, such as electrical connection bumps.

Finally, the various optical semiconductor devices 1, obtained in the various locations 22, are singulated, for example by sawing between these locations 22. In each location, the integrated-circuit chip 2 includes a portion of the complete wafer 20b of integrated circuits which is provided with holes 10, electrical connection means 8 and electrical connection elements 11, the optical plate 12 includes a portion of the optical wafer 15 and the adhesive layer 13 includes a portion of the adhesive layer 24.

The semiconductor device 1 of FIG. 1 is then obtained.

It follows that, during the thickness reduction of the substrate wafer 25 and during fabrication of the electrical connection vias 9 and back-side electrical connection means 8 and 11, the existence of the stack 18 of wafers 15 and 16 ensures the desired mechanical strength and ensures that the semiconductor devices 1 obtained comprise only the optical plate 12, formed from the wafer 15, the thickness of which may be small so that the effects of this optical plate 12 on the light rays that pass through it may be reduced, for example when the focal distance of the optical means placed in front of the integrated optical element 6 and of the plate 12 is very short.

The present invention is not limited to the examples described above. Many other variant embodiments are possible without departing from the scope defined by the appended claims.

What is claimed is:

1. A process, comprising:
producing a wafer of integrated circuits comprising a substrate wafer having at various locations a plurality of integrated circuits, said wafer of integrated circuits having a front side facing the integrated circuits;
producing a stack comprising a first wafer above to the front side of the wafer of integrated circuits and a second wafer above and removably attached to the first wafer;
opening holes in a back side of the substrate wafer at the various locations;
filling the holes with a conductive material so as to obtain electrical connection vias selectively connected to the integrated circuits;
producing a back-side external electrical connection layer on the back side of the substrate wafer at the various locations, said back-side electrical connection layer being selectively connected to the electrical connection vias;
detaching the second wafer from the first wafer; and
singulating the wafer of integrated circuits into individual semiconductor devices obtained at each of the various locations, each individual semiconductor device comprising an integrated-circuit chip that includes a portion of the wafer of integrated circuits and a plate that includes a portion of the first wafer.

2. The process according to claim 1, wherein the wafer of integrated circuits is a thick wafer comprising a thick substrate wafer, further comprising thinning the thick substrate wafer from the back side so as to obtain a thinned wafer of integrated circuits; and
wherein producing said holes comprises producing said holes in the thinned substrate wafer.

3. The process according to claim 1, wherein producing the stack comprises irremovably attaching the first wafer to the front side of the wafer of integrated circuits by way of a permanent adhesive layer, each individual semiconductor device obtained including a portion of this adhesive layer.

4. The process according to claim 3, wherein the second wafer is removably attached to the first wafer by way of a temporary or non-permanent adhesive layer.

5. The process according to claim 1, wherein the first and second wafers are made of a same material.

6. The process according to claim 1, wherein the second wafer is thicker than the first wafer.

7. The process according to claim 1, wherein the integrated circuits comprise optical elements for collecting or emitting light rays, at least the first wafer being an optical wafer that the light rays can pass through.

8. An apparatus, comprising:
a wafer of integrated circuits comprising integrated circuit devices including optical elements at various locations;
a stack of at least two wafers overlying the wafer of integrated circuits, a first one of the at least two wafers comprising an optical wafer attached to a front side of the wafer of integrated circuits where said integrated circuit devices including optical elements are provided, and a second one of the at least two wafers comprising a supporting wafer attached to the first one of the at least two wafers.

9. The apparatus according to claim 8, wherein the optical wafer is thinner than the supporting wafer.

10. The apparatus according to claim 8, wherein the optical wafer is attached to the front side of the wafer of integrated circuits by way of a permanent adhesive layer, and the supporting wafer is attached to the optical wafer by way of a temporary or non-permanent adhesive layer.

11. A semiconductor device, comprising:
a chip of integrated circuits having a reduced thickness and comprising an optical element over said integrated circuits;
an optical plate also of reduced thickness placed on the chip of integrated circuits in front of the optical element.

12. The device according to claim 11, wherein the integrated circuits, optical element and optical plate form an imaging apparatus.

13. A process, comprising:
producing an integrated circuit wafer having a first thickness and including a front side facing optical integrated circuit devices supported by the integrated circuit wafer;
permanently attaching an optical wafer having a second thickness to the front side of the integrated circuit wafer;
temporarily attaching a supporting wafer having a third thickness, greater than the second thickness, to a front side of the optical wafer;
using the supporting wafer as support while thinning the integrated circuit wafer from its back side to a fourth thickness less than the second thickness;
using the supporting wafer as support while opening holes in a back side of the thinned integrated circuit wafer;
using the supporting wafer as support while filling the holes with a conductive material so as to obtain through silicon vias passing through the thinned integrated circuit wafer;
detaching the supporting wafer from the optical wafer; and
singulating the integrated circuit wafer and permanently attached optical wafer into a plurality of individual semiconductor devices.
